(19) United States
(12) Patent Application Publication
(10) Pub. No.: US 2026/0009600 A1
(43) Pub. Date: Jan. 8, 2026

(54) THREE-DIMENSIONAL HEAT EXCHANGE DEVICE FORMING STRUCTURE

(71) Applicant: NIDEC CHAUN-CHOUNG TECHNOLOGY CORPORATION, NEW TAIPEI CITY (TW)

(72) Inventors: Hsien-Wen KUO, NEW TAIPEI CITY (TW); Shih-An YANG, NEW TAIPEI CITY (TW); Huang-Ming CHIU, NEW TAIPEI CITY (TW); Yu HAN, NEW TAIPEI CITY (TW); Cheng-Han JHENG, NEW TAIPEI CITY (TW)

(21) Appl. No.: 18/765,212

(22) Filed: Jul. 5, 2024

(51) Int. Cl. F28F 3/06

(52) U.S. Cl. CPC F28F 3/06

(57) ABSTRACT

A forming structure includes a first plate, a tube body and a second plate. The first plate has an inner surface and an outer surface and is disposed with an installing hole penetrating through the inner surface and the outer surface. The tube body corresponds to the installing hole to be disposed. The tube body has a tube portion with a closed end and an open end. The tube portion uses its closed end to be inserted into the installing hole, and the closed end penetrates out of the outer surface from the installing hole. The second plate faces the inner surface to be sealed. The open end uses an expanded end opening to approach the inner surface and then exerts pressure to be flattened and superposed on the inner surface. An upper wick structure is jointly formed on the inner surface and in the tube portion.

### BACKGROUND

### Technical Field

The disclosure relates to a heat exchanger, particularly to a three-dimensional heat exchange device forming structure.

### Related Art

A related-art three-dimensional cooler or heat exchange device is composed of a vapor chamber and multiple heat pipes. To make the vapor chamber connected with the inside of each heat pipe, an end of the heat pipe is formed to be an open shape and then welded onto the upper plate of the vapor chamber so as to implement vacuum chambers formed in the vapor chamber and the heat pipe. Thus, a heat transfer effect of a gas-liquid phase change can be performed between the vacuum chambers of the both.

However, in the related-art three-dimensional cooler or heat exchange device, to be advantageous to the communication of the inside wick, a sintered structure of powder will be filled into the wick joint between the vapor chamber and the heat pipe after the heat pipe has been welded onto the upper plate of the vapor chamber, so as to be advantageous to transmission of the working fluid via the wick structure when flowing back. However, this manner will cause that the wick structures are not substantially really continuous, which affects the wick transmission effect.

In view of this, the inventors have devoted themselves to the above-mentioned prior art, researched intensively and cooperated with the application of science to try to solve the above-mentioned problems. Finally, the invention which is reasonable and effective to overcome the above drawbacks is provided.

### SUMMARY

An object of the disclosure is to provide a three-dimensional heat exchange device forming structure, which uses the manufacturing process to make the wick structures in the plate piece and the tube body keep continuous in wick transmission.

To accomplish the above object, the disclosure provides a three-dimensional heat exchange device forming structure, which includes a first plate, at least one tube body and a second plate. The first plate has an inner surface and an outer surface and is disposed with at least one installing hole penetrating through the inner surface and the outer surface. The tube body corresponds to the installing hole to be disposed. Each tube body has a tube portion with a closed end and an open end, which are separately located at two ends thereof. The tube portion of each tube body uses its closed end to be inserted into the installing hole from the inner surface of the first plate, and the closed end penetrates out of the outer surface of the first plate from the installing hole. The second plate faces the inner surface of the first plate to be sealed. Moreover, the open end of each tube body uses an expanded end opening to approach the inner surface of the first plate first and then exerts pressure toward the inner surface of the first plate to be flattened and superposed on the inner surface of the first plate. An upper wick structure is jointly formed on the inner surface of the first plate and in the tube portion of the tube body.

### BRIEF DESCRIPTION OF THE DRAWINGS

FIG. 1 is an exploded view of the disclosure;

FIGS. 2-7 are schematic views of the manufacturing process of the disclosure;

FIG. 8 is a partially cross-sectional schematic view of the disclosure; and

FIG. 9 is a perspective assembled view of the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

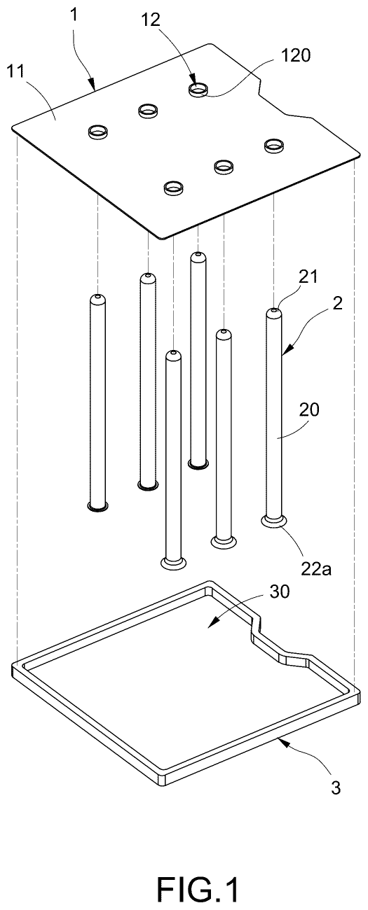

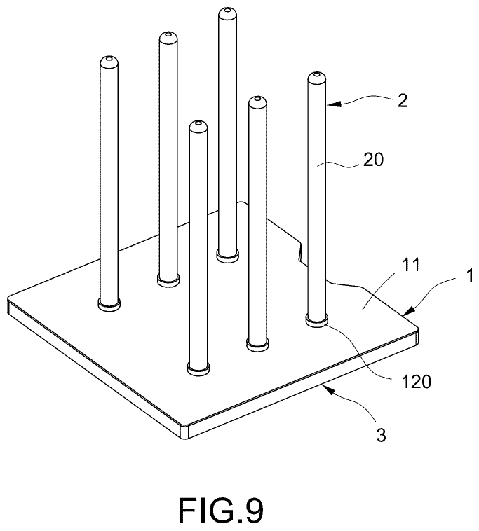

Please refer to FIGS. 1 and 9, which are an exploded view of the disclosure and a perspective assembled view of the disclosure, respectively. The disclosure provides a three-dimensional heat exchange device forming structure, which includes a first plate 1, at least one tube body 2 and a second plate 3.

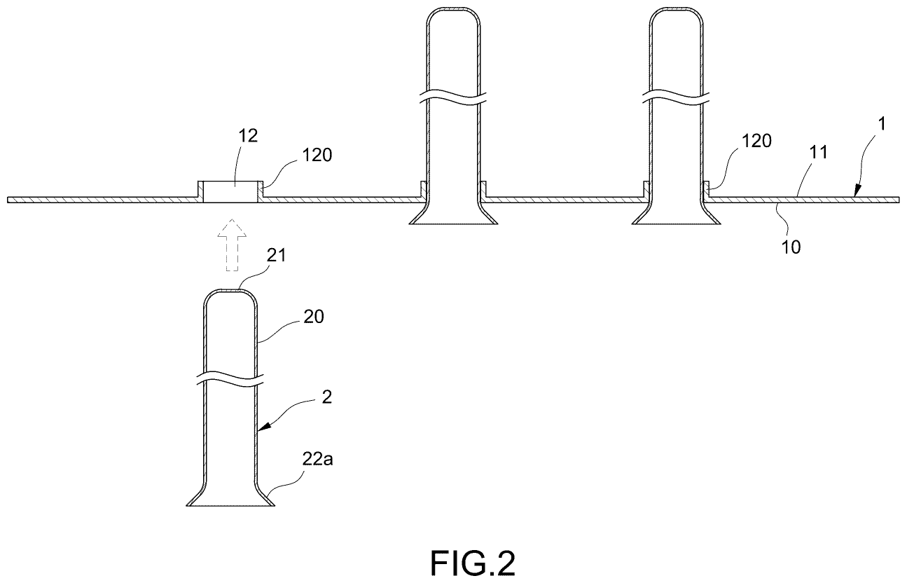

Please refer to FIGS. 1 and 2 together. The first plate 1 appears to be a plate body and has an inner surface 10 and an outer surface 11. The first plate 1 is disposed with at least one installing hole 12 penetrating through the inner surface 10 and the outer surface 11. Further, a peripheral edge of the installing hole 12 may be protruded with a hole edge 120 projecting from the outer surface 11.

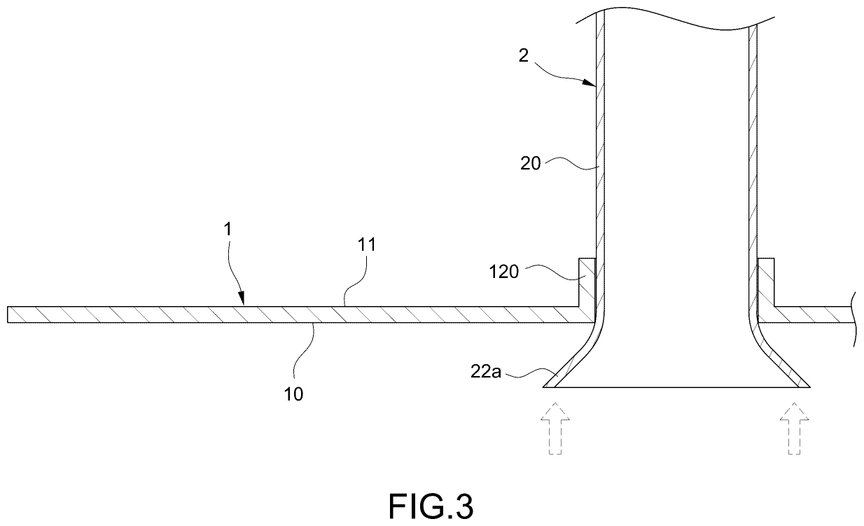

As mentioned above, the tube body 2 corresponds to the installing hole 12 to be disposed and has a tube portion 20 with a closed end 21 and an open end 22, which are separately located at two ends thereof. As shown in FIGS. 2 and 3, the open end 22 is formed into an expanded end opening 22a first. The expanded end opening 22a may appear to be a flared shape. The tube body 2 uses its closed end 21 to be inserted into the installing hole 12 from the inner surface 10 of the first plate 1 so as to make the closed end 21 of the tube body 2 penetrate out of the outer surface 11 of the first plate 1 from the installing hole 12 and make the expanded end opening 22a approach the inner surface 10 of the first plate 1.

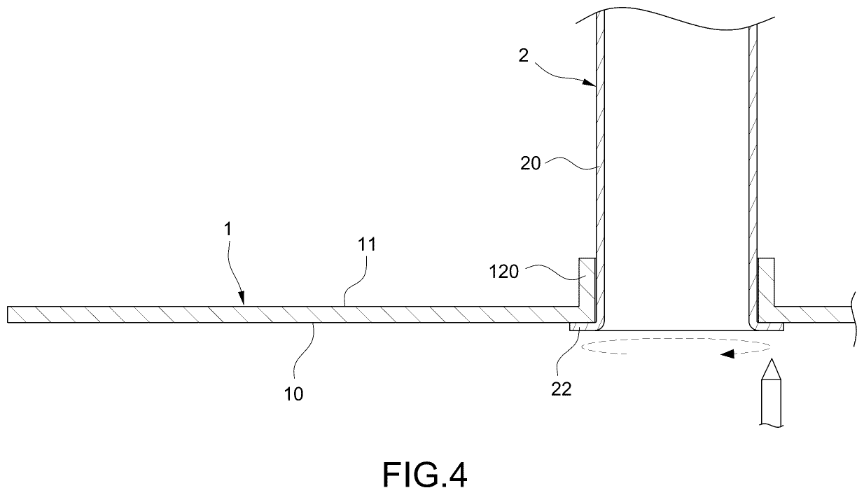

As shown in FIGS. 3 and 4, by means of punching or pressing (not shown), pressure toward the inner surface 10 of the first plate 1 (as shown by the arrow in FIG. 3) is exerted to the expanded end opening 22a to flatten and superpose the expanded end opening 22a on the inner surface 10 of the first plate 1. Further, as shown in FIG. 4, a material-free welding process such as laser welding or diffusion welding may be performed from the open end 22 toward the inner surface 10. The tube body 2 is fixedly welded to the installing hole 12 by the connection of the open end 22 and the inner surface 10 of the first plate 1 by way of laser welding or diffusion welding. Also, no weld mark will remain on the outer surface 11 of the first plate 1 to affect the appearance. In addition, the gap between the tube portion 20 of the tube body 2 and the hole edge 120 may be further sealed by welding.

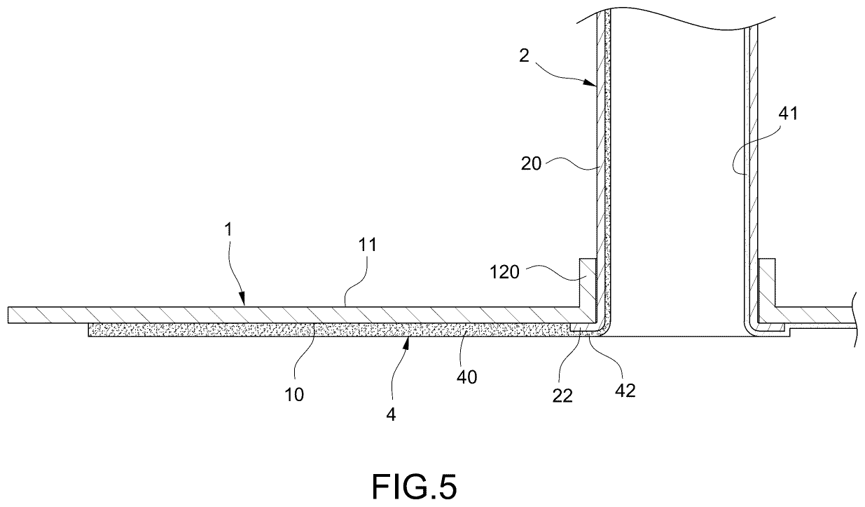

Next, as shown in FIG. 5, an upper wick structure 4 is jointly formed on the inner surface of the first plate 1 and in the tube portion 20 of the tube body 2. The upper wick structure 4 may include a plate wick portion 40 coated on the inner surface 10 of the first plate 1 and a tube wick structure 41 coated in the tube portion 20. The plate wick portion 40 and the tube wick portion 41 are connected to each other to form an integral at the expanded end opening 22a.

Moreover, the upper wick structure 4 may be formed by powder sintering, grooves formed by etching or withdrawing, or woven mesh, so the plate wick portion 40 and the tube wick portion 41 may integrally form the upper wick structure 4 by means of the abovementioned manners. Accordingly, the plate wick portion 40 of the first plate 1 and the tube wick portion 41 in the tube body 2 may be guaranteed to keep continuous without interruption in wick transmission.

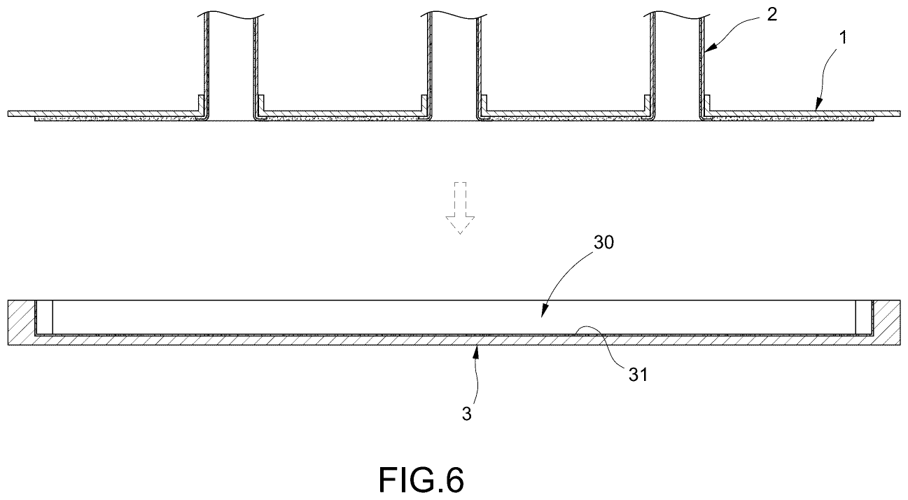

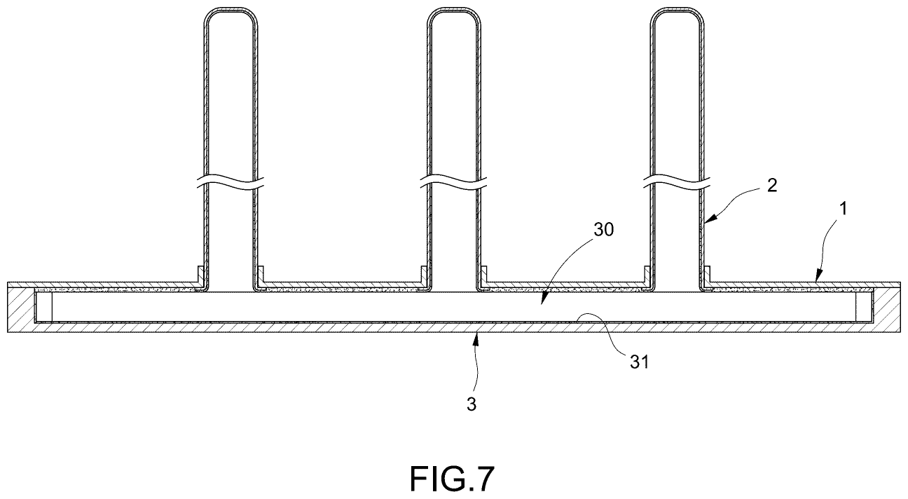

Finally, as shown in FIGS. 6 and 7, the second plate 3 and the first plate 1 are sealed and then degassed and vacuumed. Further, the second plate 3 may be formed with a recess portion in advance to allow the inner surface 10 of the first plate 1 to be toward the recess portion to be sealed so as to make a vacuum status formed between the first plate 1 and the second plate 2. The inner wall of the recess portion 30 may be disposed with a lower wick structure 31.

The lower wick structure 31 may be in contact with the plate wick portion 40 at a position adjacent to the first plate 1.

Thus, the three-dimensional heat exchange device forming structure of the disclosure may be obtained by the above composition.

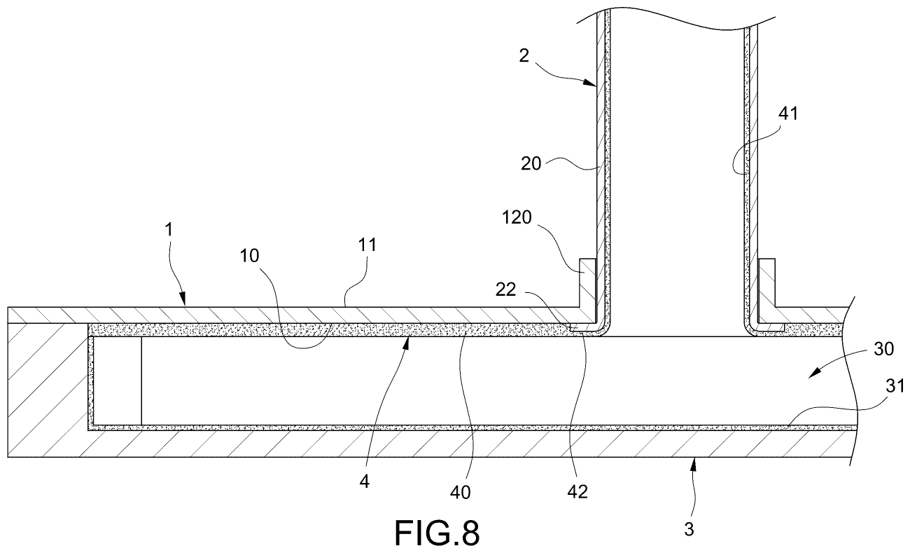

As a result, as shown in FIG. 8, the disclosure may use the above manufacturing steps to make the three-dimensional heat exchange device keep a wick (the plate wick portion 40) of an upper plate (the first plate 1) of a vapor chamber and a wick (the tube wick portion 41) of a heat pipe (the tube body 2) continuous without interruption in wick transmission. Moreover, the upper wick structure 4 further has an annular connecting portion 42 covering the expanded end opening 22a of each tube body 2 to be integrally connected between the plate wick portion 40 and the tube wick portion 41.

While this disclosure has been described by means of specific embodiments, numerous modifications and variations could be made thereto by those skilled in the art without departing from the scope and spirit of this disclosure set forth in the claims.

What is claimed is:

1. A three-dimensional heat exchange device forming structure comprising:
a first plate, comprising an inner surface and an outer surface, and disposed with at least one installing hole penetrating through the inner surface and the outer surface;
at least one tube body, corresponding to the installing hole to be disposed, each tube body comprising a tube portion with a closed end and an open end, which are separately located at two ends thereof, the tube portion of each tube body using its closed end to be inserted into the installing hole from the inner surface of the first plate, and the closed end penetrating out of the outer surface of the first plate from the installing hole; and
a second plate, facing the inner surface of the first plate to be sealed;
wherein the open end of each tube body uses an expanded end opening to approach the inner surface of the first plate first and then exerts pressure toward the inner surface of the first plate to be flattened and superposed on the inner surface of the first plate, and an upper wick structure is jointly formed on the inner surface of the first plate and in the tube portion of the tube body.

2. The three-dimensional heat exchange device forming structure of claim 1, wherein a peripheral edge of the installing hole is protruded with a hole edge projecting from the outer surface.

3. The three-dimensional heat exchange device forming structure of claim 1, wherein the expanded end opening appears to be a flared shape.

4. The three-dimensional heat exchange device forming structure of claim 1, wherein the tube body is fixedly welded to the installing hole.

5. The three-dimensional heat exchange device forming structure of claim 1, wherein the open end of the tube body is fixedly welded to the inner surface of the first plate by material-free welding.

6. The three-dimensional heat exchange device forming structure of claim 5, wherein the material-free welding is laser welding or diffusion welding.

7. The three-dimensional heat exchange device forming structure of claim 1, wherein the upper wick structure comprises a plate wick portion coated on the inner surface of the first plate and a tube wick structure coated in the tube portion, and the plate wick portion and the tube wick portion are connected to each other to form an integral at the expanded end opening.

8. The three-dimensional heat exchange device forming structure of claim 7, wherein the upper wick structure is formed by powder sintering, grooves formed by etching or withdrawing, or woven mesh.

9. The three-dimensional heat exchange device forming structure of claim 7, wherein the upper wick structure further comprises an annular connecting portion covering the expanded end opening of each tube body to be integrally connected between the plate wick portion and the tube wick portion.

10. The three-dimensional heat exchange device forming structure of claim 9, wherein the second plate is formed with a recess portion, and the inner surface of the first plate is toward the recess portion to be sealed.

11. The three-dimensional heat exchange device forming structure of claim 10, wherein an inner wall of the recess portion is disposed with a lower wick structure, and the lower wick structure is in contact with the plate wick portion at a position adjacent to the first plate.
